(19) United States
(12) Patent Application Publication
(10) Pub. No.: US 2016/0003563 A1
(43) Pub. Date: Jan. 7, 2016

(54) Composite Structure of Tungsten Copper and Molybdenum Copper with Embedded Diamond for Higher Thermal Conductivity

(71) Applicant: Sanchayan Dutta, Escondido, CA (US)

(72) Inventor: Sanchayan Dutta, Escondido, CA (US)

(73) Assignee: Thermal Management Solutions, LLC d/b/a SANTIER, San Diego, CA (US)

(21) Appl. No.: 14/746,668

(22) Filed: Jun. 22, 2015

Related U.S. Application Data
(60) Provisional application No. 62/015,469, filed on Jun. 22, 2014.
(60) Provisional application No. 62/144,679, filed on Apr. 8, 2015.

(51) Int. Cl. F28F 21/08; B23P 15/26; H05K 7/20

(52) U.S. Cl. CPC F28F 21/085; H05K 7/20509; B23P 15/26

(57) ABSTRACT

A heatsink for dissipating heat generated by electronic components comprising an outer frame of copper tungsten or copper molybdenum metal matrix composite having a cavity extending between the top and the bottom surfaces, a copper-diamond composite material within the opening, and copper plating on the top and the bottom surfaces. The heatsink also includes an array of alternating layers of copper and a material selected from the group of molybdenum and copper/molybdenum metal matrix surrounding the outer frame. The heatsink can be manufactured by press fitting at room temperature a porous isotropic diamond material in the cavity of an outer frame of porous tungsten or molybdenum, co-infiltrating the assembly under pressure with copper, press fitting at room temperature the outer frame into the layered array, and subjecting the heatsink to a temperature of approximately 800 Deg C.

### CROSS-REFERENCE TO RELATED APPLICATIONS

This application claims priority to provisional application 62/015,469, filed Jun. 22, 2014 and provisional application 62/144,679, filed Apr. 8, 2015.

### FIELD OF THE INVENTION

The invention relates to the field of packaging semiconductor devices. In particular, the invention relates to the field of hermetic, non-organic packaging of high power and/or high frequency semiconductor devices. More particularly, the invention relates to hermetic and non-hermetic packages that are closely matched to the coefficient of thermal expansion of the semiconductor/Laser devices mounted thereupon and that provide a thermally conductive pathway for heat dissipation.

### BACKGROUND OF THE INVENTION

Much of the semiconductor packaging currently in use in the electronics industry is produced from organic laminate materials; however, there still exists a need for hermetic and non hermetic, non-organic-based packaging for high power, high operating temperature, and high frequency semiconductor, as well as laser, applications where extremely high heat is generated by semiconductor and laser devices.

In operation, many of the semiconductor applications that require hermetic packaging generate significant amounts of heat that must be dissipated to maintain optimum functionality and reliability of the device. In these applications, at least a base plate of the semiconductor package is desirably formed from a thermally conductive material or structure. The efficiency with which the thermally conductive base plate can conduct waste heat away from the operating device is dependent on the thermal pathway between the semiconductor and the base plate. The most thermally efficient pathway is when the device is directly mounted onto the base plate with a continuous interface. Directly mounting the semiconductor/laser device to the base plate results in the two elements becoming mechanically coupled. If the coefficient of thermal expansion of the semiconductor/laser device and the base plate are significantly different, the mechanical integrity of the semiconductor device may be compromised. Therefore, it is important that the thermal coefficient of expansion (TCE) of the thermally conductive baseplate be generally matched to the semiconductor device.

In the past, a balance of high thermal conductivity and low thermal expansion has been attempted by forming a composite structure consisting of (1) multiple layers of ceramic material, the upper surface of the top layer and the lower surface of the bottom layer of which are (2) metallized with a low-thermal-conductivity, low-expansivity refractory metal or inorganic material (for example, tungsten or molybdenum) and (3) overlayed with a high-thermal-conductivity, high-expansivity metal (for example, copper). A low-CTE metal or alloy is one in which the CTE is less than 10 ppm per degrees Celsius. A high-thermal-conductivity metal is one in which the thermal conductivity exceeds 100 W/m*K and which has a melting temperature lower than the low-CTE metal or alloy.

Typical materials for the production of such composites are copper (Cu) and silver (Ag) for the highly-thermally-conductive metal, and molybdenum (Mo), tungsten (W), Kovar (Ni:Co:Fe alloy) for the low-thermal-expansion portion. Thermal conductivity of these material ranges from 180 W/mK to 250 W/mK. As mentioned in U.S. Pat. No. 6,727,117, diamond (Dia) can also be used.

However, with ever increasing density of transistors in a given area and increasing demand for higher power laser sources, and/or GaN compound semiconductor devices there is a need for a material that can meet this need for higher thermal performance with controlled TCE in a cost effective manner. Also along with the above requirement is high reliability over repeated thermal cycles. Such applications are tested for typical 475 thermal cycles for full life and ˜250 thermal cycles for half life. A typical thermal cycle for such accelerated life testing is −65 Deg C. to 160 Deg C.

### SUMMARY OF THE INVENTION

Semiconductor and laser dies generate substantial amount of heat due to long duty cycles. Thus an efficient material or combination of material structures/systems constructed in a specific way is required to remove wasted heat quickly from the die by either a heat sink or heat spreader design configuration. In recent times due to the need for smaller, faster and better devices, the space limitations on various applications prefers a sink design over spreader design. To achieve this goal, fundamental thermal dissipation properties of the underlying materials need to be improved. One such material is a copper diamond composite slug. Components fabricated from this material are generally known as “heatsinks” in the electronic industry. The heatsink performance in thermal dissipation is measured in terms of W/mK. The major function of the heatsink is to lower the junction temperature of the die with any interface bonding material and maintain the TCE as close as possible to that of die mounted on it. Failure to meet both of these requirement results into poor reliability and reduces the life of the die/devices.

As shown in FIG. 4, one embodiment of the present invention provides a solution to this performance demand with a heatsink structure 10 where copper-diamond composite material is embedded into a heatsink material of a given composition of copper tungsten or copper molybdenum metal matrix composite structure. Copper-molybdenum (Cu—Mo) composite has two particular advantages over copper-tungsten (Cu—W). First, because Mo is less dense than W, it takes less mass of it to produce the same reduction in thermal expansion. Therefore, if you have a Cu—Mo and a Cu—W composite material with the same thermal expansion, the Cu—Mo will have lower density, so parts made from it will weigh less. This is of particular importance in parts meant to go in aircraft and spacecraft.

The second key advantage of Cu—Mo composite is that it is more transparent to x-rays. Many manufacturers of electronic devices prefer to inspect their devices by x-ray imaging after they are sealed. Tungsten is much more opaque to x-rays than molybdenum, and the type of x-ray imaging machines normally used in this type of inspection cannot see through Cu—W, but they can see through Cu—Mo.

The typical in plane and through plane thermal conductivity without embedded copper diamond is anisotropic in nature with X-Y thermal conductivity ranging from approximately 290-350 W/mK and the Z axis thermal conductivity ranging from approximately 200-300 W/mK. The copper-molybdenum laminate submount is anisotropic in nature, and hence the thermal conductivity values are not the same on all axes.

When the same copper-molybdenum laminate material is embedded with copper diamond the resultant change in thermal conductivity in the through plane is approximately 600-700 W/mK and in plane thermal conductivity is also at approximately 600-700 w/mK in the region which is embedded by Cu-diamond. This change in fundamental thermal property of the heat sink can help run a semiconductor laser die 10 degree Celsius or more cooler. This can help in increasing performance of the overall system without increasing the system's overall physical size. Also it can help increase the power gain from the GaN power amplifier design by +2 dB or more, which is a power amplification gain of over 58.5% from input to output.

### BRIEF DESCRIPTION OF THE DRAWINGS

FIG. 1 is a graph of the thermal conductivity of various materials as compared to CuDia-CuMo Laminate (SCMC).

FIG. 2 is a graph of the thermal resistance of various materials as compared to CuDia-CuMo Laminate (SCMC).

FIG. 3 is a graph of the temperature rise under steady state conditions of various materials as compared to CuDia-CuMo laminate (SCMC).

FIG. 4 is an illustration of one embodiment of the present invention where copper-diamond composite material is embedded into a window frame structure of copper tungsten or copper molybdenum metal matrix composite.

FIG. 5 is an illustration of another embodiment of the present invention which embeds a copper-diamond composite and copper tungsten or copper molybdenum window frame structure into a copper-molybdenum or copper tungsten laminate structure.

### DETAILED DESCRIPTION OF THE INVENTION

The following steps outline one embodiment of a method to manufacture a composite structure that will provide high thermal conductivity in the X and Y plane of the layers, as well as through plane (Z-axis).

The first step is to press and first pass sinter a tungsten or molybdenum preform 20 of known porosity, and to machine, such as by milling, drilling, grinding or, punching a through cavity in the preform 20. The preform 20 is preferably a rectangular solid, with a rectangular cavity, thus comprising a “window frame” configuration. Then, the preform 20 is etched with a suitable etchant to achieve the desired surface porosity.

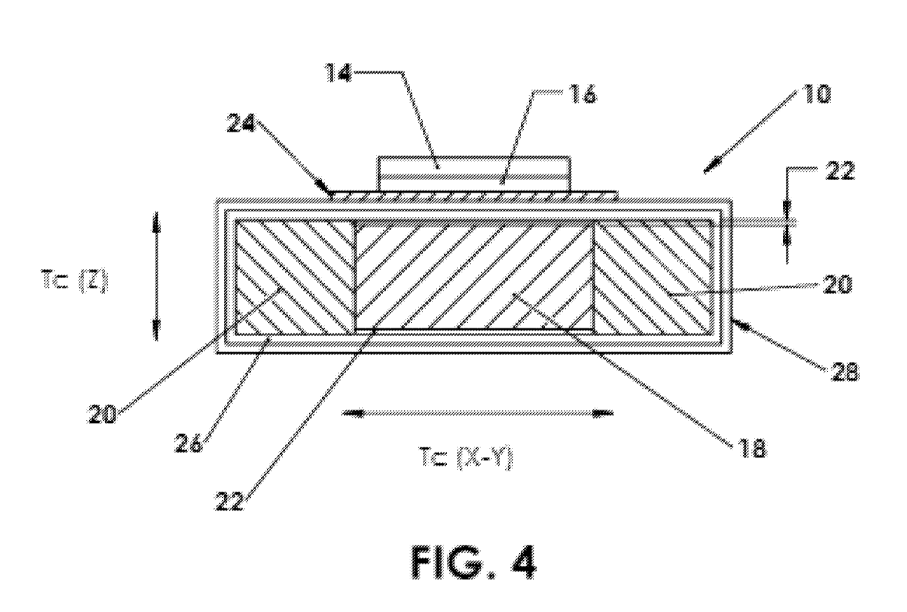

The second step is to embed a unitary insert of porous synthetic [or natural] isotropic diamond material 18 into the cavity, making sure that the upper surface of the diamond material is slightly lower than the top height of the cavity, thus forming a gap 22. The gap in the surface of the diamond material is preferably 0.002 to 0.004 inches below the surface of the preform 20. Preferably, there is a gap 20 on both the upper and lower surfaces of the window frame assembly (20 and 18), such that the assembly is symmetric and installation in the assembled heat sink 10 can be made in either orientation. The highly aligned embedded isotropic diamond insert 18 is shown in FIG. 4.

Next, the diamond 18 and copper tungsten or copper molybdenum porous material 20 window frame structure is co-infiltrated under pressure with copper to produce a near homogenous matrix of tungsten-diamond-copper or molybdenum-diamond-copper. This infiltrated material structure is then coated with a copper plating 26 on the top and the bottom surface to achieve desired surface properties.

Once this assembly is complete, it is preferably post processed, such as with nickel and/or gold plating 28, and/or lapping and eutectic gold tin coating 24. The heat sink 10 may then be fitted with a die base 16 and die 14.

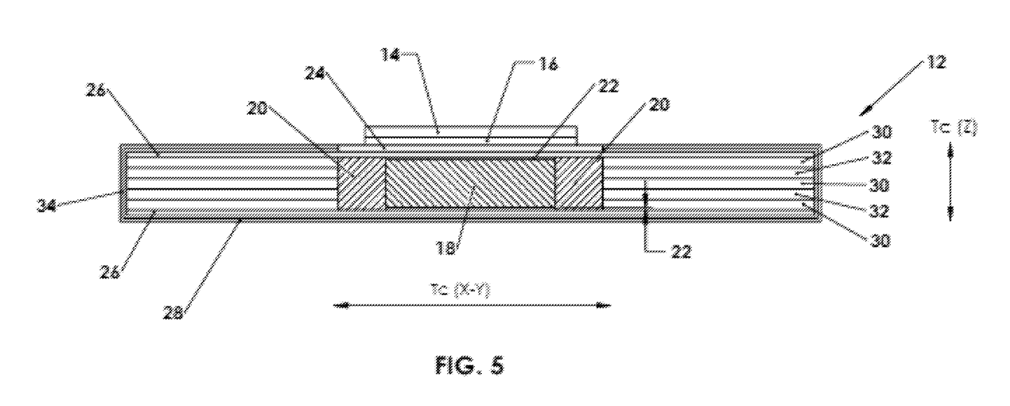

In another embodiment of the present invention, the diamond 18 and copper tungsten or copper molybdenum material 20 window frame structure described above can also be further embedded in a copper laminate structure. For example, alternating copper-molybdenum-copper laminates (CMC) or copper-copper/molybdenum metal matrix-copper (SCMC) layers in a core of 3, 5, 7, 9 and so on total layers can be used. Molybdenum metal matrix layers infiltrated with approximately 30% copper are preferably used to improve adhesion and conductivity between the layers. As shown in FIG. 5, this embodiment of the present invention provides a solution to heat dissipation demand by embedding a copper-diamond composite 18 and copper tungsten or copper molybdenum material 20 window frame structure into a copper-molybdenum or copper tungsten laminate structure (30 and 32), which is laminated with heat and pressure to achieve high thermal conductivity in the through plane and in plane.

The manufacturing process to build such heat sinking submounts is basically to embed a diamond insert of a particular porosity into a pre-determined copper-molybdenum laminate structure. This compound structure is then electroplated with copper and finally finished with additional nickel and gold coating on the top and bottom surfaces to generate a surface finish of Ra 32 or better. This addition of thin extra copper adds to the thermal resistance of the part and lowers the overall thermal conductivity slightly from approximately 900 W/mK to 600-700 W/mK, as compared to copper which is at 400 W/mK.

As shown in FIG. 5, the typical cross-section of such a cu-diamond embedded heat sink is manufactured as follows.

The first step is to press and first pass sinter a tungsten or molybdenum preform 20 of known porosity, and to machine, such as by milling, drilling, grinding or , punching a through cavity in the preform 20 thus forming a window frame configuration. Then, the preform 20 is etched with a suitable etchant to achieve the desired surface porosity.

The second step is to embed a unitary insert of porous synthetic [or natural] isotropic diamond material 18 into the cavity, making sure that the upper surface of the diamond material is slightly lower than the top height of the cavity, thus forming a gap 22. The surface of the diamond insert 18 is preferably 0.001 to 0.002 inches below the surface of the preform window frame 20. Preferably, there is a gap 22 on both the upper and lower surfaces of the window frame assembly (20 and 18), such that the assembly is symmetric and installation in the assembled heat sink 10 can be made in either orientation.

Next, the diamond 18 and copper tungsten or copper molybdenum porous material 20 window frame structure is co-infiltrated under pressure with copper to produce a near homogenous matrix of tungsten-diamond-copper or molybdenum-diamond-copper.

This infiltrated material structure is then coated with a copper plating 26 on the top and the bottom surface to achieve desired surface properties.

This diamond insert 18 and window frame 20 assembly is inserted in a copper laminate structure, for example, copper-molybdenum-copper laminates or copper-copper/molybdenum-copper metal matrix corer of 3, 5, 7, 9 and so on total layers. The CTE of the materials is preferably configured in a 3 level hierarchy to achieve compressive stress at the interface between the CuDia insert and the WCu and/or MoCu window frame, and also at the interface between the window frame and the surrounding copper-molybdenum-copper or copper-copper/molybdenum-copper laminate structure as shown in FIG. 5. For example, a CuDia insert having a CTE of 6.5 can be press fit at room temperature into a surrounding WCu and/or MoCu window frame having a CTE of 7.0 to 7.5. Then the CuDia insert is co-infiltrated with copper at copper melting temperature, approximately 1,100 deg C., into the window frame.

Similarly, the WCu and/or MoCu window frame can be press fit at room temperature into the surrounding laminate structure housing base having a CTE of 8.0 to 8.5. The most preferred range of CTE differential between the interfaces is approximately 5-10%, with 11-25% as a maximum. These same ranges of CTE differential also apply for any subsequent interfaces, if required, depending on the design.

This completed heatsink assembly is then subjected to the higher temperatures, such as 800 Deg C., and the laminate structure housing base 30 and 32, with the greatest CTE, exhibits the most expansion, and thus also the greatest residual shrinkage upon cooling to room or operating temperatures. This greater residual shrinkage causes a compressive stress against the window frame which exhibits less residual shrinkage. This compressive stress results in an interference fit which enhances thermal conductivity by reducing the thermal impedance across the junction between the laminate structure housing base 30 and 32 the window frame 20. Similarly, the relatively greater residual shrinkage between the window frame 20 and the diamond insert 18, which exhibits less residual shrinkage, causes a compressive stress which results in an interference fit and reduced thermal impedance across the junction between the window frame 20 and the diamond insert 18.

Once this assembly is complete, it is post processed, such as with nickel 28 and gold plating 34.

This completed heatsink structure 12 provides an extremely high thermally conductive path for semiconductor or laser dies when they are bonded using standard industrial practices and at the same time this structure can pass full life cycle testing (Min 475 thermal cycles) as in the thermal conductivity of the structure is not affected by multiple thermal cycling. A typical completed construction of such heatsink with semiconductor die is shown in FIG. 5.

The typical in plane (X and Y axes) and through plane thermal conductivity without embedded diamond is same on all axis and equals to 180 W/mK to 250 w/mK, depending on the percentage of copper infiltrated into porous Tungsten or Molybdenum. The Tungsten Copper or Copper Molybdenum submounts are isotropic in nature and hence the Thermal conductivity values are same on all axes.

By contrast, when the same tungsten copper or copper molybdenum material is embedded with isotropic diamond material, as outlined above in steps 1 thru 4, the resultant thermal conductivity in the through plane is 550 W/mK and in plane thermal conductivity is 550 w/mK. Thus, the thermal properties are the same in all three axes, as the composite structure behaves as a near isotropic structure. Also due to the laminate surrounding structure which is providing the compressive stress around the central core provides an efficient heat dissipation path sideways which creates a flatter heat cone under the device which will slow the rate of rise of temperature and plays a big role in improving the device reliability.

This change in fundamental thermal property of the heatsink can help run semiconductor devices and laser dies/devices considerably cooler and hence improve the performance and the overall life of such devices, along with the reliability of systems using these devices.

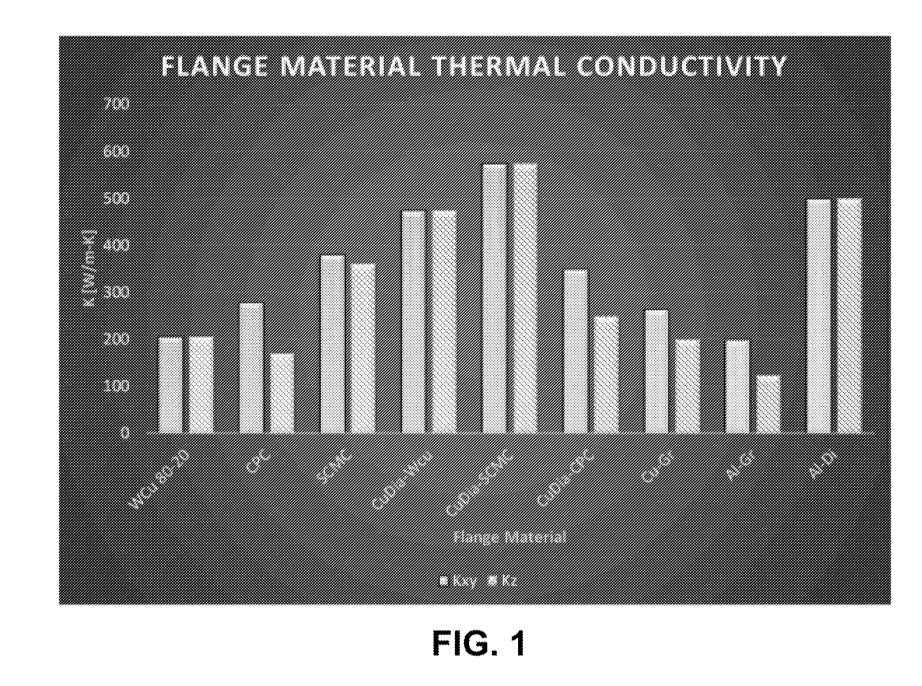

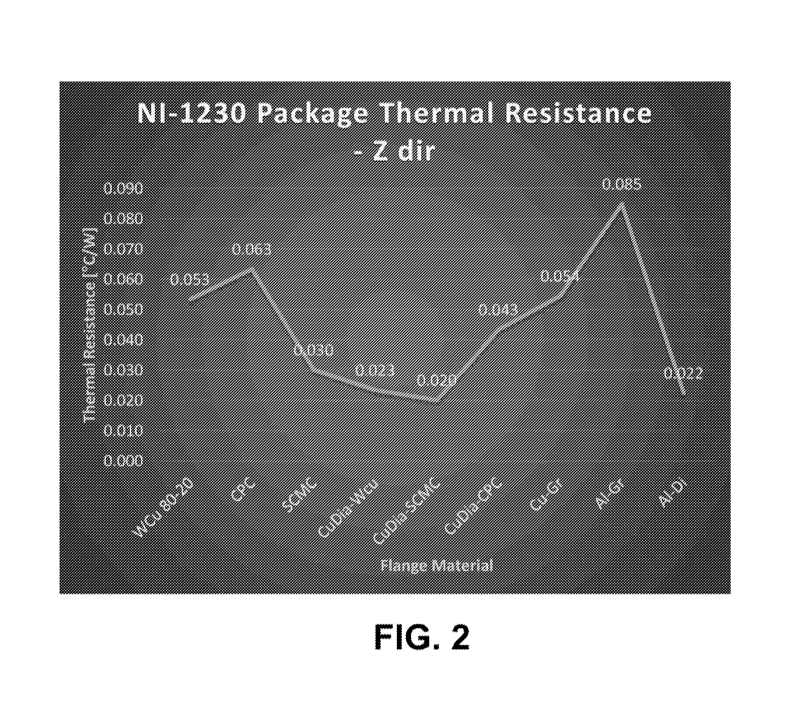

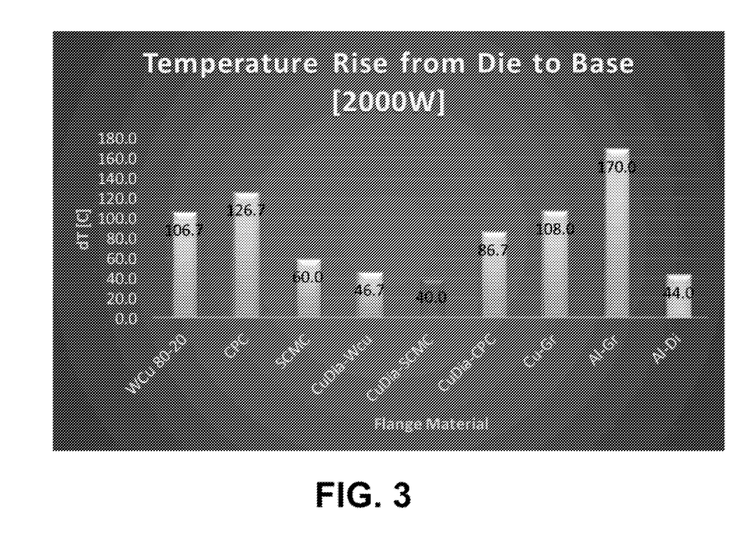

Simulated performance data on a typical CuDia in a CuMo window frame assembly in a CuMo laminate structure is shown in FIGS. 1-3. These simulated data are based upon a typical 1.230 inch length RF module outline used in various RF applications including cellular base stations. FIG. 1 depicts the thermal conductivity of various materials as compared to CuDia-CuMo Laminate (SCMC). FIG. 2 depicts the thermal resistance of various materials as compared to CuDia-CuMo Laminate (SCMC). FIG. 3 depicts the temperature rise under steady state (conditions of various materials as compared to CuDia-CuMo laminate SCMC).

Accordingly, the present invention comprises a heatsink for dissipating heat generated by electronic components comprising an outer frame of copper tungsten or copper molybdenum metal matrix composite having a cavity extending between the top and the bottom surfaces, a copper-diamond composite material within the opening, and copper plating on the top and the bottom surfaces. The heatsink may further comprise an array of alternating layers of copper and a material selected from the group of molybdenum and copper/molybdenum metal matrix surrounding the outer frame. The heatsink can be manufactured by press fitting at room temperature a porous isotropic diamond material in the cavity of an outer frame of porous tungsten or molybdenum, co-infiltrating the assembly under pressure with copper, press fitting at room temperature the outer frame into the layered array, and subjecting the heatsink to a temperature of approximately 800 Deg C.

I claim:

1. A heatsink for dissipating heat generated by electronic components comprising
an outer frame of copper molybdenum metal matrix composite having a cavity extending between the top and the bottom surfaces, and
a copper-diamond composite material within the opening.

2. The heatsink of claim 1 further comprising copper plating on the top and the bottom surfaces.

3. The heatsink of claim 1 further comprising an array of alternating layers of copper and a material selected from the group of molybdenum and copper/molybdenum metal matrix surrounding the outer frame.

4. The heatsink of claim 1 wherein the top surface of the copper-diamond composite material is recessed below the top surface of the outer frame.

5. The heatsink of claim 4 wherein the recess is approximately 0.002 to 0.004 inches.

6. The heatsink of claim 1 manufactured by a process comprising the step of installing a porous isotropic diamond material in the cavity of an outer frame of porous molybdenum and co-infiltrating the assembly under pressure with copper.

7. The heatsink of claim 3 wherein the top surface of the copper-diamond composite material is recessed below the top surface of the outer frame.

8. The heatsink of claim 7 wherein the recess is approximately 0.001 to 0.002 inches.

9. The heatsink of claim 7 further comprising copper plating on the top and the bottom surfaces.

10. The heatsink of claim 9 further comprising nickel plating on the top and the bottom surfaces.

11. The heatsink of claim 10 further comprising gold plating on the top and the bottom surfaces.

12. The heatsink of claim 3 wherein the top surface of the copper-diamond composite material is recessed below the top surface of the outer frame.

13. The heatsink of claim 1 wherein the outer frame has a CTE greater than the CTE of the copper-diamond composite material and the heatsink is manufactured by a process comprising the step of press fitting at room temperature a porous isotropic diamond material in the cavity of an outer frame of porous molybdenum and co-infiltrating the assembly under pressure with copper.

14. The heatsink of claim 13 wherein the CTE differential between the outer frame and the copper-diamond composite material is in the range of approximately 5-25%.

15. The heatsink of claim 13 wherein the CTE differential between the outer frame and the copper-diamond composite material is in the range of approximately 5-10%.

16. The heatsink of claim 13 further comprising an array of alternating layers of copper and a material selected from the group of molybdenum and copper/molybdenum metal matrix surrounding the outer frame, and wherein the layered array has a CTE greater than the CTE of the outer frame, and the heatsink is manufactured by a process comprising the step of press fitting at room temperature the outer frame into the layered array and subjecting the heatsink to a temperature of approximately 800 Deg C.

17. The heatsink of claim 16 wherein the CTE differential between the layered array and the outer frame is in the range of approximately 5-25%.

18. The heatsink of claim 16 wherein the CTE differential between the layered array and the outer frame is in the range of approximately 5-10%.

19. A heatsink for dissipating heat generated by electronic components comprising
an outer frame of copper tungsten metal matrix composite having a cavity extending between the top and the bottom surfaces, and
a copper-diamond composite material within the opening.

20. The heatsink of claim 19 further comprising copper plating on the top and the bottom surfaces.

21. The heatsink of claim 19 further comprising an array of alternating layers of copper and a material selected from the group of molybdenum and copper/molybdenum metal matrix surrounding the outer frame.

22. The heatsink of claim 19 wherein the top surface of the copper-diamond composite material is recessed below the top surface of the outer frame.

23. The heatsink of claim 22 wherein the recess is approximately 0.002 to 0.004 inches.

24. The heatsink of claim 19 manufactured by a process comprising the step of installing a porous isotropic diamond material in the cavity of an outer frame of porous tungsten and co-infiltrating the assembly under pressure with copper.

25. The heatsink of claim 21 wherein the top surface of the copper-diamond composite material is recessed below the top surface of the outer frame.

26. The heatsink of claim 25 wherein the recess is approximately 0.001 to 0.002 inches.

27. The heatsink of claim 25 further comprising copper plating on the top and the bottom surfaces.

28. The heatsink of claim 27 further comprising nickel plating on the top and the bottom surfaces.

29. The heatsink of claim 280 further comprising gold plating on the top and the bottom surfaces.

30. The heatsink of claim 21 wherein the top surface of the copper-diamond composite material is recessed below the top surface of the outer frame.

31. The heatsink of claim 19 wherein the outer frame has a CTE greater than the CTE of the copper-diamond composite material and the heatsink is manufactured by a process comprising the step of press fitting at room temperature a porous isotropic diamond material in the cavity of an outer frame of porous tungsten and co-infiltrating the assembly under pressure with copper.

32. The heatsink of claim 31 wherein the CTE differential between the outer frame and the copper-diamond composite material is in the range of approximately 5-25%.

33. The heatsink of claim 31 wherein the CTE differential between the outer frame and the copper-diamond composite material is in the range of approximately 5-10%.

34. The heatsink of claim 31 further comprising an array of alternating layers of copper and a material selected from the group of molybdenum and copper/molybdenum metal matrix surrounding the outer frame, and wherein the layered array has a CTE greater than the CTE of the outer frame, and the heatsink is manufactured by a process comprising the step of press fitting at room temperature the outer frame into the layered array and subjecting the heatsink to a temperature of approximately 800 Deg C.

35. The heatsink of claim 34 wherein the CTE differential between the layered array and the outer frame is in the range of approximately 5-25%.

36. The heatsink of claim 34 wherein the CTE differential between the layered array and the outer frame is in the range of approximately 5-10%.

37. A method for manufacturing a heatsink comprising the steps of:
machining a cavity extending between the top and the bottom surfaces in an outer frame of copper molybdenum metal matrix composite;
installing a porous isotropic diamond material in the cavity; and
co-infiltrating the assembly under pressure with copper.

38. The method of claim 37 further comprising plating the top and the bottom surfaces with copper.

39. The method of claim 37 wherein the step of installing a porous isotropic diamond material in the cavity comprises press fitting at room temperature the porous isotropic diamond material into the cavity of the outer frame.

40. The method of claim 37 further comprising machining a cavity extending between the top and the bottom surfaces in an array of alternating layers of copper and a material selected from the group of molybdenum and copper/molybdenum metal matrix, and installing the outer frame into the cavity.

41. The method of claim 40 wherein the step of installing the outer frame into the cavity in the array comprises press fitting at room temperature the outer frame into the layered array and subjecting the heatsink to a temperature of approximately 800 Deg C.

42. The method of claim 41 wherein the outer frame has a CTE greater than the CTE of the copper-diamond composite material and

[symbol]

43. The method of claim 42 wherein the CTE differential between the outer frame and the copper-diamond composite material is in the range of approximately 5-25%.

44. The method of claim 42 wherein the CTE differential between the outer frame and the copper-diamond composite material is in the range of approximately 5-10%.
